(19) United States
(12) Patent Application Publication
(10) Pub. No.: US 2010/0300527 A1
(43) Pub. Date: Dec. 2, 2010

(54) SUBSTRATE FOR COMPOUND SEMICONDUCTOR SOLAR CELL

(75) Inventors: Hiroshi Okamura, Kudamatsu-shi (JP); Hirofumi Yamano, Kudamatsu-shi (JP); Masanobu Matsubara, Kudamatsu-shi (JP); Shigeyoshi Nishiyama, Kudamatsu-shi (JP)

Correspondence Address: BROWDY AND NEIMARK, P.L.L.C.;624 NINTH STREET, NW, SUITE 300, WASHINGTON, DC, 20001-5303, US

(73) Assignee: TOYO KOHAN CO., LTD., Tokyo (JP)

(21) Appl. No.: 12/790,213

(22) Filed: May 28, 2010

Related U.S. Application Data
(60) Provisional application No. 61/185,353, filed on Jun. 9, 2009.

(30) Foreign Application Priority Data
May 28, 2009 (JP) 2009-129610

(51) Int. Cl. H01L 31/0216

(52) U.S. Cl. 136/256

(57) ABSTRACT

[Problem] A substrate for a compound semiconductor solar cell which maintains excellent elasticity even after a high temperature process at the time of forming a thin film is provided.

[Means for Resolution] The substrate for a compound semiconductor solar cell is formed of a steel plate, and a Cr layer having a coating film quantity of 300 to 8000 mg/m² is formed on a surface of the substrate on a side to which a solar cell layer is laminated. The Cr layer having a coating film quantity of 500 to 3000 mg/m² may be formed on the surface of the substrate on a side to which the solar cell layer is laminated, and a film forming temperature of the solar cell layer is less than 550° C. The Cr layer having a coating film quantity of 2000 to 8000 mg/m² may be formed on the surface of the substrate on a side to which the solar cell layer is laminated, and a film forming temperature of the solar cell layer is more than 800° C. The Cr layer having a coating film quantity of 2000 to 5000 mg/m² may be formed on the surface of the substrate on a side to which the solar cell layer is laminated, and a film forming temperature of the solar cell layer is not less than 550° C. and not more than 800° C. A quantity of Mn component in a steel strip is not more than 2 wt % . A quantity of Fe component in the steel strip is not more than 98 wt %.

### TECHNICAL FIELD

The present invention relates to a flexible substrate for a compound semiconductor solar cell.

### BACKGROUND ART

Conventionally, as a substrate for a flexible compound semiconductor solar cell such as a CuInSeO₂ (CIS) type solar cell or a Cu(In, Ga)Se₂ (CIGS) type solar cell, a metal strip has been proposed (see patent document 1). This metal strip is made of stainless steel in general.

The metal strip described in patent document 1 is provided with a film including an insulation layer doped with a mixture made of one kind of alkali metal or plural kinds of alkali metals. The thermal expansion coefficient of the above-mentioned metal strip material is 12×10⁻⁶K⁻¹ at a temperature range from 0 to 600° C. The above-mentioned insulation layer includes at least one kind of oxide layer, and the oxide layer is made of any one kind of dielectric oxide selected from a group consisting of Al₂O₃, TiO₂, HfO₂, Ta₂O₅, Nb₂O₅ and a mixture of these materials, and preferably is made of Al₂O₃ and/or TiO₂.

Further, with respect to the substrate for a compound semiconductor solar cell, it has been known that when Fe and other elements which constitute components of the substrate diffuse into a solar cell layer, this diffusion of substrate components brings about the lowering of conversion efficiency. In view of the above, there has been known a technique which forms a diffusion preventing layer on the substrate for suppressing the diffusion of the substrate elements into the solar cell layer on the substrate.

Further, patent document 2 discloses a solar cell in which a barrier layer made of a thin conductive body, an extremely thin insulation material or the like, a back contact layer made of molybdenum, a p-type semiconductor layer and the like are formed on a substrate made of glass, metal, ceramic or plastic.

### PRIOR ART LITERATURE

### Patent Document

### [Patent Document 1] JP 2007-502536 A

### [Patent Document 2] JP 2008-520103 A

### SUMMARY OF THE INVENTION

### Task to be Solved by the Invention

However, in the disclosure of patent document 1, the specific constitution of the diffusion preventing layer is not clearly described. Further, in an actual operation, although a film forming step for a compound semiconductor solar cell includes a high-temperature treatment step, it is not clearly described whether the diffusion preventing layer exhibits a diffusion preventing function under specific conditions. Under such circumstances, there has been a drawback that kinds of substrates with which a compound semiconductor solar cell can be manufactured without bringing about the lowering of electricity generation efficiency is indefinite.

Further, although the barrier layer is formed by sputtering in the solar cell disclosed in patent document 2, such a sputtering process has a drawback that the facility cost is pushed up so that a raw material used in the manufacture of the solar cell cannot be supplied at a low cost.

The present invention has been made under such circumstances, and has clarified a specific substrate which can be effectively used in the manufacture of a compound semiconductor solar cell which includes high-temperature heat treatment.

That is, it is an object of the present invention to provide a substrate for a compound semiconductor solar cell in which on a surface of a steel strip which maintains excellent elasticity even after a high temperature process at the time of forming a thin film of the compound semiconductor solar cell, a film layer which can suppress the heat-diffusion intrusion of a steel-strip-contained element which brings about lowering of cell conversion efficiency into the thin film layer is formed by electrolytic plating.

### Means for Solving the Task

(1) The present invention is directed to a substrate for a compound semiconductor solar cell, wherein the substrate is formed of a steel plate, and a Cr layer having a coating film quantity of 300 to 8000 mg/m² is formed on a surface of the substrate on a side to which a solar cell layer is laminated.

(2) In the substrate for a compound semiconductor solar cell having the constitution (1), the substrate is formed of the steel plate, the Cr layer having a coating film quantity of 500 to 3000 mg/m² is formed on the surface of the substrate on a side to which the solar cell layer is laminated, and a film forming temperature of the solar cell layer is less than 550° C.

(3) In the substrate for a compound semiconductor solar cell having the constitution (1), the substrate is formed of the steel plate, the Cr layer having a coating film quantity of 2000 to 8000 mg/m² is formed on the surface of the substrate on the side to which the solar cell layer is laminated, and a film forming temperature of the solar cell layer is more than 800° C.

(4) In the substrate for a compound semiconductor solar cell having the constitution (1), the substrate is formed of the steel plate, the Cr layer having a coating film quantity of 2000 to 5000 mg/m² is formed on the surface of the substrate on a side to which the solar cell layer is laminated, and a film forming temperature of the solar cell layer is not less than 550° C. and not more than 800° C.

(5) In the substrate for a compound semiconductor solar cell of the present invention having any one of the constitutions (1) to (4), a quantity of Mn component in a steel strip is not more than 2 wt %.

(6) In the substrate for a compound semiconductor solar cell of the present invention having the constitutions (1) to (4), a quantity of Fe component in the steel strip is not more than 98 wt %.

### ADVANTAGE OF THE INVENTION

By clarifying the film constitution of the diffusion barrier layer, the present invention provides a substrate which can prevent the diffusion of impurity elements of the substrate into the solar cell layer which brings about lowering of power generation efficiency.

Further, by adopting an electrolytic plating method is adopted as a method for forming the diffusion barrier layer, productivity is enhanced and an inexpensive material can be supplied.

### BRIEF DESCRIPTION OF DRAWINGS

FIG. 1 is an explanatory view schematically showing a cross section of a substrate for a compound semiconductor solar cell according to the present invention;

FIG. 2 is a result of measurement of elements on a surface of the substrate after heat treatment (550° C.×30 minutes); and

FIG. 3 is a result of measurement of elements on a surface of the substrate after heat treatment (800° C.×15 minutes).

### MODE FOR CARRYING OUT THE INVENTION

A substrate for a compound semiconductor solar cell of the present invention is characterized in that the substrate for a flexible compound semiconductor solar cell which is formed of a steel plate (steel strip), and a Cr layer having a coating film quantity of 300 to 8000 mg/m² is formed on a surface of the substrate on a side to which a solar cell layer is laminated.

A diffusion barrier layer which can suppress the diffusion of elements such as Fe, Ni, Mn, Si, Al or the like harmful to conversion efficiency into the solar cell layer even in a high temperature process at the time of forming a thin film is formed by electrolytic treatment.

Further, it is desirable to form a Cr layer also on a back surface side of the steel plate as a corrosion resistance layer.

Here, the steel strip may be a surface treated steel plate to which plating made of Ni, Zn, Sn or the like is applied.

### <Diffusion Barrier Layer>

As the diffusion barrier layer which can suppress the diffusion of elements such as Fe, Ni, Mn, Si, Al or the like harmful to conversion efficiency into the solar cell layer even in a high temperature process at the time of forming a thin film, the formation of the Cr layer is named.

A thickness of the Cr layer on a condensing surface side is set to 300 to 8000 mg/m². This is because that a manufacturing step of the compound semiconductor solar cell includes a step where treatment is performed at a high temperature so that a diffusion barrier layer having a thickness of at least 300 mg/m² is necessary. On the other hand, even when the diffusion barrier layer having the thickness exceeding 8000 mg /m² is formed, the element diffusion effect is saturated and is no more increased, and the increase of the thickness of the diffusion barrier layer pushes up a cost. Accordingly, the upper limit of the thickness of the diffusion barrier layer is set to 8000 mg/m².

For example, when the heat treatment which is performed after the formation of the thin film on the substrate includes the high temperature treatment of 550° C., it is desirable to set the thickness of the diffusion barrier layer to approximately 500 to 5000 mg/m². When the thickness of the diffusion barrier layer exceeds 5000 mg/m², the Fe diffusion prevention effect is lowered. The reason is that in performing the heat treatment in a temperature zone of approximately 550° C., cracks occur in a thermal stress when the thickness of the Cr plating layer is large so that the Fe diffusion prevention effect is lowered.

Further, in performing the heat treatment in a temperature zone of 800° C. or more, it is desirable to set the thickness of the diffusion barrier layer to a value which falls within a range from 2000 to 8000 mg/m².

Provided that the thickness of the diffusion barrier layer falls within approximately from 2000 to 5000 mg/m², when the heat treatment is performed within a range from 550° C. to 800° C., the diffusion barrier layer can perform an effective diffusion prevention function.

Further, by taking a case where a solar cell is installed outdoors into consideration, it is desirable to provide a corrosion resistant treatment layer also on a side opposite to a condensing plane side of the substrate, that is, on a reverse condensing plane side. When the corrosion resistant treatment layer is made of Cr, a thickness of the corrosion resistant treatment layer may preferably be 80 to 500 mg/m², and more particularly 100 to 200 mg/m².

### <Steel Strip>

A steel strip which constitutes a background of the substrate is required to have a low thermal expansion coefficient (TCE) to prevent the occurrence of peeling or cracks in a stacked Cr layer. Accordingly, it is desirable to set the linear expansion coefficient (TCE) of the steel strip to not more than 16×10⁻⁶/K within a temperature range from 0 to 800° C.

Since a film is formed with heat treatment within a temperature range from 500 to 800° C., it is necessary to impart the sufficient heat resistance to the steel strip to be used. Further, to prevent the occurrence of a phenomenon that components contained in the steel strip are diffused thus causing the degradation of cell performance, the steel strip material is required to contain the following components as inevitable components for this end.

That is, the steel strip components are constituted of C≦0.2% (% being mass (wt) %, this definition being applicable throughout this specification), Si≦0.5%, Mn≦2.0%, P≦0.06%, S≦0.04%, Ti≦0.15% or Nb≦0.1%, Fe≦98% and unavoidable impurities.

The reason of limitation of the main elements contained in the steel strip is described hereinafter.

C is an important element for the steel strip to acquire strength after a solar cell layer is formed as a film. However, when a quantity of C is excessively large, a rolling burden during hot rolling and cold rolling is increased thus obstructing productivity including the deterioration of shape. Accordingly, an upper limit of C is set to 0.20%.

Although it is unnecessary to particularly designate Si here, in the same manner as Mn, the excessive presence of Si causes lowering of productivity including the increase of a burden during cold rolling, the deterioration of shape, the obstruction of sheet passing property during a continuous annealing step. Accordingly, in the present invention, an upper limit of an Si component is set to 0.5%.

Mn is, in the same manner as C, an element necessary for the steel strip to acquire high strength after the formation of the solar cell layer as a film. However, when a quantity of Mn is excessively large, there exists a possibility that power generation efficiency of a solar cell is lowered or a rolling burden is increased and hence, an upper limit of Mn is set to 2.0%.

P is a component which makes crystal grains fine and can increase strength of a cold rolled steel plate and hence, the addition of P at a fixed rate is desirable. On the other hand, P is segregated in a crystal grain boundary thus making the steel plate brittle. Accordingly, a quantity of P is set to 0.06% or less.

S is an impurity component which causes red shortness during hot rolling and hence, it is desirable that a quantity of S is as small as possible. However, it is impossible to completely prevent the intrusion of S in view of raw materials or the like, and the desulphurization in steps is also limited and hence, the presence of a small quantity of S is not avoidable. The hot shortness attributed to a small quantity of residual S can be reduced by Mn and hence, an upper limit of S component is set to 0.04%.

With respect to Ti and Nb, both elements form nitrocarburized material and hence, Ti and Nb have an effect to make crystal grains fine thus enhancing strength of the steel strip. However, when either one of these elements is contained in the steel strip excessively, the nitrocarburized material becomes coarse and hence, a strength enhancing effect becomes saturated. Further, the recrystallization temperature during continuous annealing is also elevated thus pushing up a cost. Accordingly, Ti and Nb are set to ranges of Ti≦0.15%, Nb≦0.1% respectively, and the steel strip includes one kind or two kinds of Ti or Nb.

A quantity of Fe is set to 98% or less for lowering power generation efficiency relative to the compound semiconductor solar cell.

### <Steel Making>

The steel strip which forms a background of the substrate is produced in such a manner that raw materials are melted in a converter or an electric furnace, a slab member is produced by adjusting the composition thereof within the above-mentioned composition range, and the slab members are subjected to following steps.

### <Hot Rolling>

Firstly, the slab member whose composition is adjusted is subjected to hot rolling so as to reduce a plate thickness of the slab member to 1.6 to 2.5 mm. When the plate thickness is small, a burden during hot rolling is increased. Accordingly, a lower limit of the plate thickness is set to 1.6 mm. On the other hand, when the plate thickness is large, a burden is increased during cold rolling which follows the hot rolling and hence, an upper limit of the plate thickness is set to 2.5 mm.

In the hot rolling step, the hot rolling is performed by setting a heating temperature of the slab member within the above-mentioned composition range to 1100° C. or more, and by setting a winding temperature to 500° C. or more. When the heating temperature of the slab member is less than 1100° C., the positive decomposition solid solution of N becomes in short and a hot rolling burden is increased. Accordingly, the heating temperature of less than 1100° C. is not desirable.

Further, the winding temperature is set to 500° C. to 700° C. When the winding temperature is low, the strength of the hot rolled steel plate is increased. Since the increase of the strength of the hot rolled steel plate is not desirable during cold rolling, a lower limit of the winding temperature is set to 500° C.

On the other hand, when the winding temperature exceeds 700° C., the formation of scales is accelerated during hot rolling so that a burden is increased at the time of descaling during pickling whereby an upper limit is set to 700° C.

The above-mentioned hot rolled steel plate is subjected to the usual pickling, cold rolling and annealing, and is formed into a finished product having a predetermined plate thickness by cold rolling finally.

### <Thickness of Substrate>

The substrate is formed of a steel strip, and has a thickness of 0.01 to 0.2 mm. The thickness may preferably be 0.025 to 0.05 mm.

### <Surface Roughness>

It is desirable to make a surface of the substrate after Cr plating as smooth as possible and hence, the surface roughness of the substrate is an important parameter. As the surface roughness of the substrate, it is preferable to set Ra (center line surface roughness), Rz (10 point average height of irregularities), and Rmax (maximum height) such that Ra≦0.1 μm, Rz≦0.3 μm, Rmax≦0.5 μm.

When any one of Ra, Rz and Rmax exceeds a predetermined value, that is, when Ra exceeds 0.1 μm, Rz exceeds 0.3 μm or Rmax exceeds 0.5 μm, an Mo film which is formed as an electrode cannot be uniformly formed so that the steel strip is exposed whereby the power generation efficiency of the substrate as a compound semiconductor solar cell is deteriorated.

### <Yield Stress>

It is desirable to set a yield stress (Yp) of the substrate after Cr plating to 200 MPa or more. It is desirable to set the yield stress (Yp) to 200 MPa or more even after heat history corresponding to thin-film-forming heat treatment temperature of 550° C. or more.

The reason is as follows. That is, the substrate before the solar cell layer is formed is not particularly limited, and is subjected to hot working of approximately 500 to 800° C. and hence, the substrate is subjected to heat treatment and is softened.

The substrate for a compound semiconductor solar cell of the present invention has a plate thickness of 0.2 mm or less, and more preferably 0.025 to 0.05 mm. Since the substrate for a compound semiconductor solar cell is extremely thin as a substrate, when the substrate is softened, operability and handling of the substrate become difficult. Accordingly, it is desirable that the yield stress is set to 300 MPa or more and the tensile strength is set to 400 MPa or more before the formation of the film, and the yield stress is set to 200 MPa or more and the tensile strength is set to 300 MPa or more after the formation of the film.

### <Manufacturing Method of Substrate>

To maximize the flexibility (resiliency) of the solar cell, it is necessary to make the Cr layer stacked on the steel strip strongly adhered to the steel strip.

For this end, cleaning treatment is applied to the steel strip before stacking. That is, firstly, for removing a residual oil content or the like which may adversely influence the stacking treatment efficiency, and the adhesiveness and quality of the film, the steel strip is cleaned using a proper method.

Next, electrolytic plating treatment is applied to the steel strip in line.

### Conditions of <Electrolytic Plating Treatment>

As conditions of electrolytic plating treatment, the following conditions are preferably named.

As a plating bath, a sulfuric acid bath can be used. That is, a bath in which sulfuric acid (0.3 g/L) is added to chromic acid (CrO₃): 30 to 250 g/L can be named. Further, it is also desirable to use various kinds of assistants for precipitating metal Cr and oxide Cr in a stable manner.

As the assistants, for example, NaF, sulfuric acid (in case of sulfuric acid bath), ammonium fluoride and the like can be named.

The plating conditions are set as follows.

current density: 10 to 70 A/dm², preferably 20 to 40 A/dm²

bath temperature: 30 to 60° C., preferably 40 to 50° C.

pH: 1 or less (strong acid)

### EMBODIMENT

### Embodiment 1

Amaterial whose components are adjusted such that C: 0.06%, Si:0.2%, Mn:1.6%, P:0.012%, S:0.010% is subjected to hot rolling and, thereafter, cold rolling is performed in several steps with a recrystallization step sandwiched between these steps thus eventually manufacturing cold-rolled steel strip having a thickness of approximately 0.1 mm.

Specimens are prepared by applying Cr plating of 500, 1000, 1500, 2000, 3000, 5000, 8000 mg/m² to one surface (condensing plane side) of the steel strip and by applying Cr plating of 200 mg/m² to another surface (non condensing plane side) of the steel strip.

To obtain the above-mentioned Cr plating having a thickness of 500 to 8000 mg/m², an electrolytic time is changed. For example, to obtain the Cr plating having a thickness of 2000 mg/m² on the steel plate, plating treatment is performed at current density of 30 A/dm² for 40 seconds. Thereafter, the specimen is heated in a vacuum at a temperature of 550° C. for 30 minutes or is heated at a temperature of 800° C. for 15 minutes.

The surface roughness (Ra) of the substrate to which Cr plating is applied on the condensing plane side is 0.05 μm.

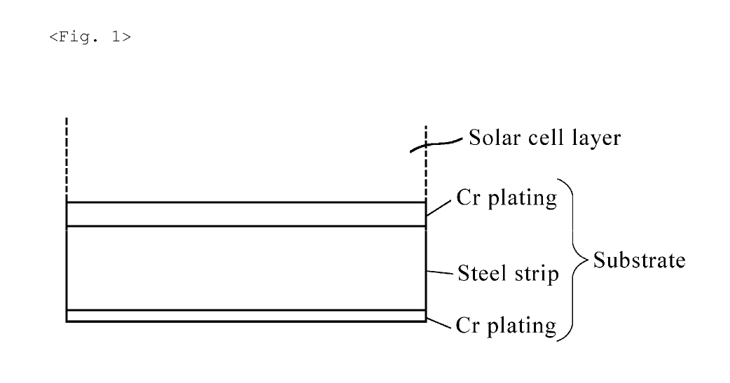

FIG. 1 is an explanatory view schematically showing a cross section of the substrate for a compound semiconductor solar cell.

Table 1 and Table 2 show values of a measurement result of elements on a Cr plating surface measured by an SIMS device after applying heat treatment to the substrates according to the present invention.

TABLE 1

| | | treatment condition | |
|---|---|---|---|
| | | 550° C. × 30 minutes treated material | |
| | | relative element quantity with respect to SUS (%) | |
| specimen | | Fe | Mn |
| SUS430 | | 100 | 100 |
| chromium | 500 | 4 | 12 |
| film | 1000 | 1 | 2 |
| quantity | 1500 | 2 | 1 |
| of present | 2000 | 1 | 1 |
| invention | 3000 | 1 | 1 |
| (mg/m²) | 5000 | 10 | 7 |
| | 8000 | 33 | 14 |

TABLE 2

| | | treatment condition | |
|---|---|---|---|
| | | 800° C. × 15 minutes treated material | |
| | | relative element quantity with respect to SUS (%) | |
| specimen | | Fe | Mn |
| SUS430 | | 100 | 100 |
| chromium | 500 | 46 | 143 |
| film | 1000 | 42 | 158 |
| quantity | 1500 | 28 | 103 |
| of present | 2000 | 4 | 19 |
| invention | 3000 | 1 | 1 |
| (mg/m²) | 5000 | 1 | 1 |
| | 8000 | 0 | 1 |

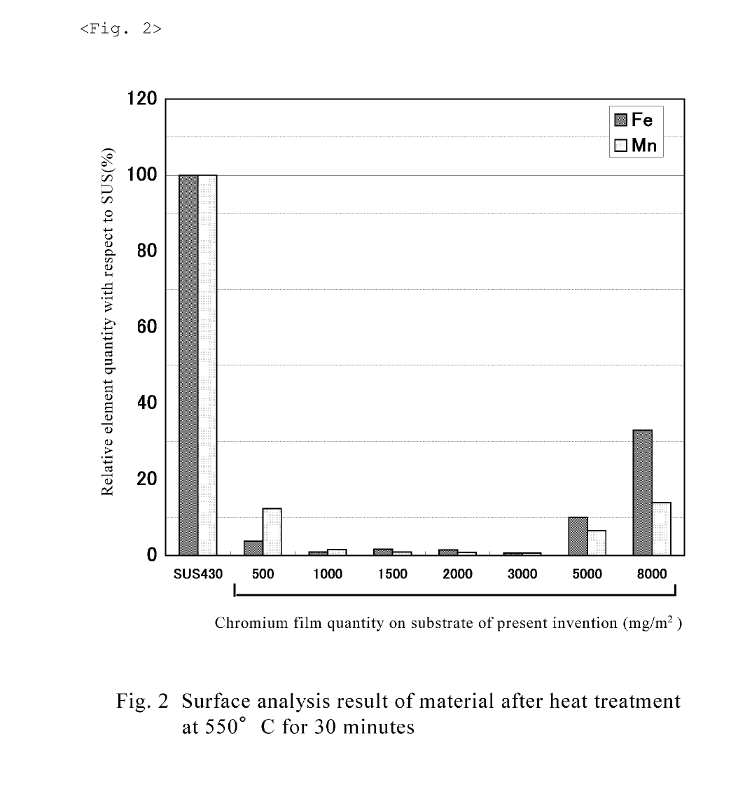

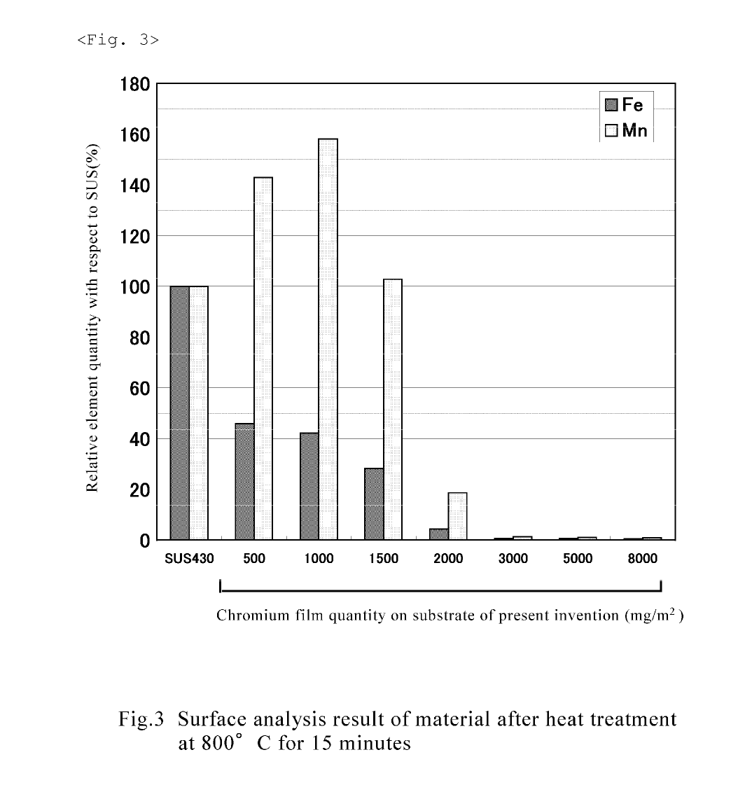

Further, FIG. 2 and FIG. 3 are graphs showing a result of measurement of elements on a Cr plating surface (by an SIMS device) after applying heat treatment to the substrates of the present invention.

The results shown in FIGS. 2 and 3 evaluate a diffusion prevention effect of an Fe element in the steel strip which forms a base of the substrate.

As can be understood from FIG. 2 and FIG. 3 which show the result of the evaluation, when the substrate is subjected to heat treatment at a temperature of 550° C. for 30 minutes, compared to a comparison material (SUS 430), with respect to the substrates of the present invention where the thickness of Cr plating is 500 mg/m² or more, a quantity of Fe on the surface of the substrate can be largely reduced so that the Fe diffusion prevention effect is recognized (see FIG. 2).

Further, when the substrate is subjected to heat treatment at a temperature of 800° C. for 15 minutes, or when the thickness of Cr plating is set to 2000 mg/m² or more, a quantity of Fe on the surface of the substrate is largely reduced compared to the comparison material so that the Fe element diffusion prevention effect is recognized (see FIG. 3).

### INDUSTRIAL APPLICABILITY

Since the film constitution of the diffusion barrier layer is clarified with respect to the substrate for a compound semiconductor solar cell according to the present invention, the diffusion of impurity elements in a steel strip into the solar cell layer which brings about lowering of power generation efficiency can be prevented. Further, by adopting an electrolytic plating method as a method for forming the diffusion barrier layer, productivity is enhanced. A cheap material can be supplied thus remarkably enhancing industrial applicability.

1. A substrate for a compound semiconductor solar cell, wherein the substrate is formed of a steel plate, and a Cr layer having a coating film quantity of 300 to 8000 mg/m² is formed on a surface of the substrate on a side to which a solar cell layer is laminated.

2. The substrate for a compound semiconductor solar cell according to claim 1, wherein the substrate is formed of the steel plate, the Cr layer having a coating film quantity of 500 to 3000 mg/m² is formed on the surface of the substrate on a side to which the solar cell layer is laminated, and a film forming temperature of the solar cell layer is less than 550° C.

3. The substrate for a compound semiconductor solar cell according to claim 1, wherein the substrate is formed of the steel plate, the Cr layer having a coating film quantity of 2000 to 8000 mg/m² is formed on the surface of the substrate on a side to which the solar cell layer is laminated, and a film forming temperature of the solar cell layer is more than 800° C.

4. The substrate for a compound semiconductor solar cell according to claim 1, wherein the substrate is formed of the steel plate, the Cr layer having a coating film quantity of 2000 to 5000 mg/m² is formed on the surface of the substrate on a side to which the solar cell layer is laminated, and a film forming temperature of the solar cell layer is not less than 550° C. and not more than 800° C.

5. The substrate for a compound semiconductor solar cell according to claim 1, wherein a quantity of Mn component in a steel strip is not more than 2 wt %.

6. The substrate for a compound semiconductor solar cell according to claim 1, wherein a quantity of Fe component in the steel strip is not more than 98 wt %.
